(19) United States
(12) Patent Application Publication
(10) Pub. No.: US 2023/0389355 A1
(43) Pub. Date: Nov. 30, 2023

(54) MANUFACTURING METHOD OF DISPLAY DEVICE AND CVD DEVICE

(71) Applicant: Japan Display Inc., Tokyo (JP)

(72) Inventors: Noriyuki HIRATA, Tokyo (JP); Hiraaki KOKAME, Tokyo (JP)

(73) Assignee: Japan Display Inc., Tokyo (JP)

(21) Appl. No.: 18/324,192

(22) Filed: May 26, 2023

(30) Foreign Application Priority Data
May 27, 2022 (JP) 2022-087000

(51) Int. Cl. H10K 59/12; H01J 37/32; H10K 59/80; C23C 16/458; C23C 16/455; C23C 16/34; C23C 16/56; C23C 16/50; C23C 16/44

(52) U.S. Cl. CPC H10K 59/1201; H01J 37/32357; H01J 37/32862; H01J 37/32449; H10K 59/873; C23C 16/4583; C23C 16/45565; C23C 16/345; C23C 16/56; C23C 16/50; C23C 16/4405; H01J 2237/334

(57) ABSTRACT

According to one embodiment, a manufacturing method of a display device includes forming a sealing layer. The forming the sealing layer includes a deposition process of introducing a material gas into a chamber, depositing silicon nitride on a processing substrate, stopping introduction of the material gas and evacuating a residual gas of inside of the chamber, and an etching process of introducing a cleaning gas into the chamber through a same route as the material gas, performing anisotropic dry etching for removing part of the silicon nitride deposited on the processing substrate, and evacuating a residual gas of the inside of the chamber. A combination of the deposition process and the etching process is performed at least twice.

### CROSS-REFERENCE TO RELATED APPLICATIONS

This application is based upon and claims the benefit of priority from Japanese Patent Application No. 2022-087000, filed May 27, 2022, the entire contents of which are incorporated herein by reference.

### FIELD

Embodiments described herein relate generally to a manufacturing method of a display device and a CVD device.

### BACKGROUND

Recently, display devices to which an organic light emitting diode (OLED) is applied as a display element have been put into practical use. This display element comprises a pixel circuit including a thin-film transistor, a lower electrode connected to the pixel circuit, an organic layer which covers the lower electrode, and an upper electrode which covers the organic layer. The organic layer includes functional layers such as a hole transport layer and an electron transport layer in addition to a light emitting layer.

In the process of manufacturing such a display element, a technique which prevents the reduction in reliability has been required.

### BRIEF DESCRIPTION OF THE DRAWINGS

FIG. 1 is a diagram showing a configuration example of a display device DSP.

FIG. 2 is a diagram showing an example of the layout of subpixels SP1, SP2 and SP3.

FIG. 3 is a schematic cross-sectional view of the display device DSP along the A-B line of FIG. 2.

FIG. 4 is a flow diagram for explaining an example of the manufacturing method of the display device DSP.

FIG. 5 is a diagram for explaining the manufacturing method of the display device DSP.

FIG. 6 is a diagram for explaining the manufacturing method of the display device DSP.

FIG. 7 is a diagram for explaining the manufacturing method of the display device DSP.

FIG. 8 is a diagram for explaining the manufacturing method of the display device DSP.

FIG. 9 is a diagram for explaining the manufacturing method of the display device DSP.

FIG. 10 is a diagram for explaining a configuration example of a CVD device 100.

FIG. 11 is a diagram for explaining the formation method of a sealing layer.

FIG. 12 is a cross-sectional view for explaining the formation method of the sealing layer.

FIG. 13 is a cross-sectional view for explaining the formation method of the sealing layer.

FIG. 14 is a cross-sectional view for explaining the formation method of the sealing layer.

### DETAILED DESCRIPTION

Embodiments described herein aim to provide a manufacturing method of a display device and a CVD device such that the reduction in reliability can be prevented.

In general, according to one embodiment, a manufacturing method of a display device comprises preparing a processing substrate by forming a lower electrode above a substrate, forming a rib comprising an aperture overlapping the lower electrode, and forming a partition including a lower portion located on the rib and an upper portion located on the lower portion and protruding from a side surface of the lower portion, forming an organic layer on the lower electrode in the aperture, forming an upper electrode which is located on the organic layer and is in contact with the partition, forming a cap layer on the upper electrode, and forming a sealing layer which is located on the cap layer and is in contact with the partition. The forming the sealing layer includes, after the processing substrate in which the cap layer is formed is carried into a chamber, a deposition process of introducing a material gas into the chamber, depositing silicon nitride on the processing substrate, stopping introduction of the material gas and evacuating a residual gas of inside of the chamber, and following the deposition process, an etching process of introducing a cleaning gas into the chamber through a same route as the material gas, performing anisotropic dry etching for removing part of the silicon nitride deposited on the processing substrate, and evacuating a residual gas of the inside of the chamber. A combination of the deposition process and the etching process is performed at least twice.

According to another embodiment, a CVD device comprises a chamber, a stage provided inside the chamber and supporting a processing substrate which is carried in, a shower head facing the stage, a material gas supply mechanism which supplies a material gas to the shower head, and a cleaning gas supply mechanism which supplies a cleaning gas to the shower head. The CVD device is configured to introduce the material gas into the chamber via the shower head, ground the stage, supply high-frequency electricity to the shower head, deposit silicon nitride on the processing substrate, and stop introduction of the material gas, and introduce the cleaning gas into the chamber via the shower head, supply high-frequency electricity to the stage, and perform anisotropic dry etching for removing part of the silicon nitride deposited on the processing substrate.

The embodiments can provide a manufacturing method of a display device and a CVD device such that the reduction in reliability can be prevented.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as a first direction. A direction parallel to the Y-axis is referred to as a second direction. A direction parallel to the Z-axis is referred to as a third direction. When various elements are viewed parallel to the third direction Z, the appearance is defined as a plan view. When terms indicating the positional relationships of two or more structural elements, such as “on”, “above” “between” and “face”, are used, the target structural elements may be directly in contact with each other or may be spaced apart from each other as a gap or another structural element is interposed between them. The positive direction of the Z-axis is referred to as an upward direction or a direction to an upper side.

The display device of the present embodiment is an organic electroluminescent display device comprising an organic light emitting diode (OLED) as a display element, and could be mounted on a television, a personal computer, a vehicle-mounted device, a tablet, a smartphone, a mobile phone, etc.

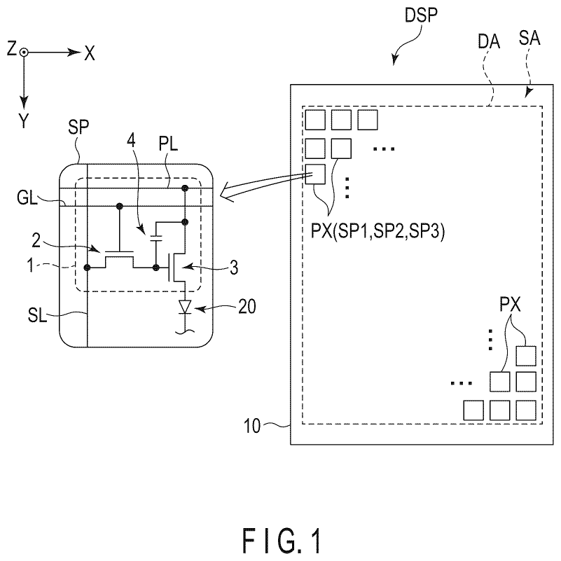

FIG. 1 is a diagram showing a configuration example of a display device DSP.

The display device DSP comprises a display area DA which displays an image and a surrounding area SA around the display area DA on an insulating substrate 10. The substrate 10 may be glass or a resinous film having flexibility.

In the present embodiment, the substrate 10 is rectangular as seen in plan view. It should be noted that the shape of the substrate 10 in plan view is not limited to a rectangular shape and may be another shape such as a square shape, a circular shape or an elliptic shape.

The display area DA comprises a plurality of pixels PX arrayed in matrix in a first direction X and a second direction Y. Each pixel PX includes a plurality of subpixels SP. For example, each pixel PX includes subpixel SP1 which exhibits a first color, subpixel SP2 which exhibits a second color and subpixel SP3 which exhibits a third color. The first color, the second color and the third color are different colors. Each pixel PX may include a subpixel SP which exhibits another color such as white in addition to subpixels SP1, SP2 and SP3 or instead of one of subpixels SP1, SP2 and SP3. It should be noted that the combination of subpixels is not limited to three elements. The combination may consist of two elements or may consist of four or more elements by adding subpixel SP4, etc., to subpixels SP1 to SP3.

Each subpixel SP comprises a pixel circuit 1 and a display element 20 driven by the pixel circuit 1. The pixel circuit 1 comprises a pixel switch 2, a drive transistor 3 and a capacitor 4. The pixel switch 2 and the drive transistor 3 are, for example, switching elements consisting of thin-film transistors.

The gate electrode of the pixel switch 2 is connected to a scanning line GL. One of the source electrode and the drain electrode of the pixel switch 2 is connected to a signal line SL. The other one is connected to the gate electrode of the drive transistor 3 and the capacitor 4. In the drive transistor 3, one of the source electrode and the drain electrode is connected to a power line PL and the capacitor 4, and the other one is connected to the anode of the display element 20.

It should be noted that the configuration of the pixel circuit 1 is not limited to the example shown in the figure. For example, the pixel circuit 1 may comprise more thin-film transistors and capacitors.

The display element 20 is an organic light emitting diode (OLED) as a light emitting element, and may be called an organic EL element.

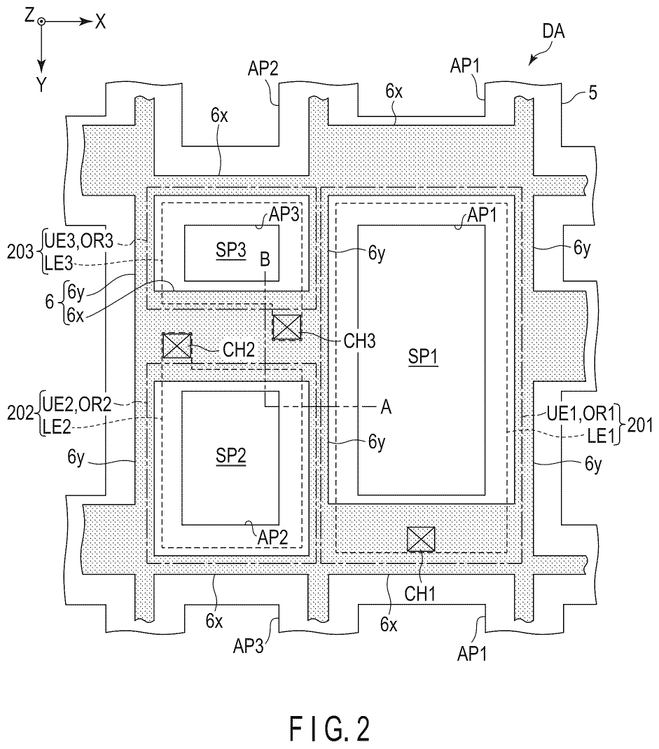

FIG. 2 is a diagram showing an example of the layout of subpixels SP1, SP2 and SP3.

In the example of FIG. 2, subpixels SP2 and SP3 are arranged in the second direction Y. Further, each of subpixels SP2 and SP3 is adjacent to subpixel SP1 in the first direction X.

When subpixels SP1, SP2 and SP3 are provided with this layout, in the display area DA, a column in which subpixels SP2 and SP3 are alternately provided in the second direction Y and a column in which a plurality of subpixels SP1 are provided in the second direction Y are formed. These columns are alternately arranged in the first direction X.

It should be noted that the layout of subpixels SP1, SP2 and SP3 is not limited to the example of FIG. 2. As another example, subpixels SP1, SP2 and SP3 in each pixel PX may be arranged in order in the first direction X.

A rib 5 and a partition 6 are provided in the display area DA. The rib 5 comprises apertures AP1, AP2 and AP3 in subpixels SP1, SP2 and SP3, respectively.

The partition 6 overlaps the rib 5 as seen in plan view. The partition 6 comprises a plurality of first partitions 6x extending in the first direction X and a plurality of second partitions 6y extending in the second direction Y. The first partitions 6x are provided between the apertures AP2 and AP3 which are adjacent to each other in the second direction Y and between two apertures AP1 which are adjacent to each other in the second direction Y. Each second partition 6y is provided between the apertures AP1 and AP2 which are adjacent to each other in the first direction X and between the apertures AP1 and AP3 which are adjacent to each other in the first direction X.

In the example of FIG. 2, the first partitions 6x and the second partitions 6y are connected to each other. Thus, the partition 6 is formed into a grating shape surrounding the apertures AP1, AP2 and AP3 as a whole. In other words, the partition 6 comprises apertures in subpixels SP1, SP2 and SP3 in a manner similar to that of the rib 5.

Subpixels SP1, SP2 and SP3 comprise display elements 201, 202 and 203, respectively, as the display elements 20.

Subpixel SP1 comprises a lower electrode LE1, an upper electrode UE1 and an organic layer OR1 overlapping the aperture AP1. Subpixel SP2 comprises a lower electrode LE2, an upper electrode UE2 and an organic layer OR2 overlapping the aperture AP2. Subpixel SP3 comprises a lower electrode LE3, an upper electrode UE3 and an organic layer OR3 overlapping the aperture AP3.

In the example of FIG. 2, the outer shapes of the lower electrodes LE1, LE2 and LE3 are shown by dotted lines, and the outer shapes of the organic layers OR1, OR2 and OR3 and the upper electrodes UE1, UE2 and UE3 are shown by alternate long and short dash lines. The peripheral portion of each of the lower electrodes LE1, LE2 and LE3 overlaps the rib 5. It should be noted that the outer shape of each of the lower electrodes, organic layers and upper electrodes shown in the figure does not necessarily reflect the accurate shape.

The lower electrode LE1, the upper electrode UE1 and the organic layer OR1 constitute the display element 201 of subpixel SP1. The lower electrode LE2, the upper electrode UE2 and the organic layer OR2 constitute the display element 202 of subpixel SP2. The lower electrode LE3, the upper electrode UE3 and the organic layer OR3 constitute the display element 203 of subpixel SP3.

The lower electrodes LE1, LE2 and LE3 correspond to, for example, the anodes of the display elements. The upper electrodes UE1, UE2 and UE3 correspond to the cathodes of the display elements or a common electrode.

The lower electrode LE1 is connected to the pixel circuit 1 (see FIG. 1) of subpixel SP1 through a contact hole CH1. The lower electrode LE2 is connected to the pixel circuit 1 of subpixel SP2 through a contact hole CH2. The lower electrode LE3 is connected to the pixel circuit 1 of subpixel SP3 through a contact hole CH3.

In the example of FIG. 2, the area of the aperture AP1 is greater than that of the aperture AP2, and the area of the aperture AP2 is greater than that of the aperture AP3. In other words, the area of the lower electrode LE1 exposed from the aperture AP1 is greater than that of the lower electrode LE2 exposed from the aperture AP2. The area of the lower electrode LE2 exposed from the aperture AP2 is greater than that of the lower electrode LE3 exposed from the aperture AP3.

For example, the display element 201 of subpixel SP1 is configured to emit light in a blue wavelength range. The display element 202 of subpixel SP2 is configured to emit light in a green wavelength range. The display element 203 of subpixel SP3 is configured to emit light in a red wavelength range.

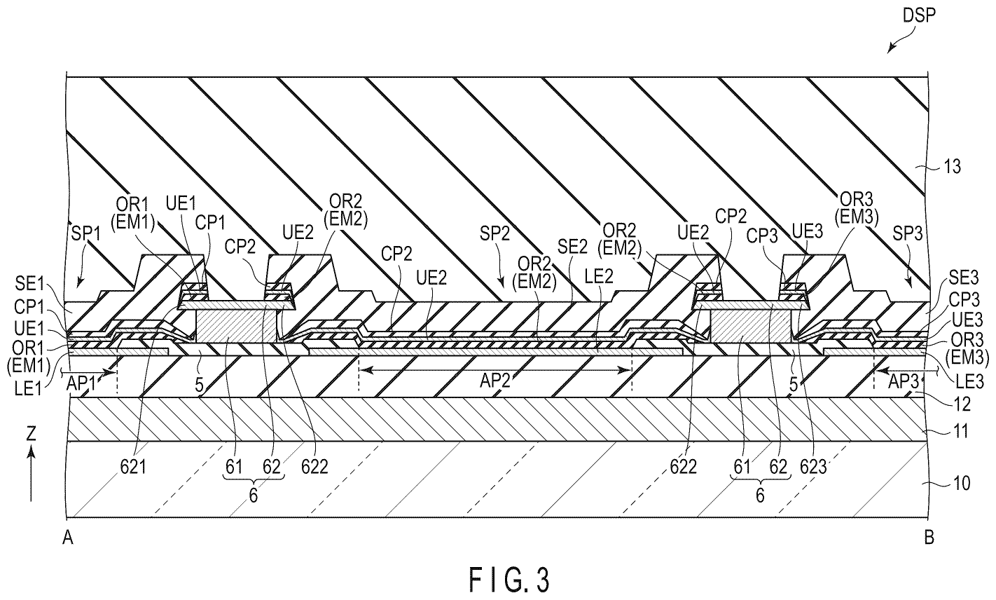

FIG. 3 is a schematic cross-sectional view of the display device DSP along the A-B line of FIG. 2.

A circuit layer 11 is provided on the substrate 10 described above. The circuit layer 11 includes various circuits such as the pixel circuit 1 shown in FIG. 1 and various lines such as the scanning line GL, the signal line SL and the power line PL. The circuit layer 11 is covered with an insulating layer 12. The insulating layer 12 functions as a planarization film which planarizes the irregularities formed by the circuit layer 11.

The lower electrodes LE1, LE2 and LE3 are provided on the insulating layer 12. The rib 5 is provided on the insulating layer 12 and the lower electrodes LE1, LE2 and LE3. The end portions of the lower electrodes LE1, LE2 and LE3 are covered with the rib 5. In other words, the end portions of the lower electrodes LE1, LE2 and LE3 are provided between the insulating layer 12 and the rib 5. Of the lower electrodes LE1, LE2 and LE3, between the lower electrodes which are adjacent to each other, the insulating layer 12 is covered with the rib 5.

The partition 6 includes a lower portion (stem) 61 provided on the rib 5 and an upper portion (shade) 62 provided on the lower portion 61. The lower portion 61 of the partition 6 shown on the left side of the figure is located between the aperture AP1 and the aperture AP2. The lower portion 61 of the partition 6 shown on the right side of the figure is located between the aperture AP2 and the aperture AP3. The upper portion 62 has a width greater than that of the lower portion 61. By this configuration, in FIG. 3, the both end portions of the upper portion 62 protrude relative to the side surfaces of the lower portion 61. This shape of the partition 6 may be called an overhang shape. Of the upper portion 62, a portion which protrudes to the aperture AP1 relative to the lower portion 61 is referred to as a protrusion 621. A portion which protrudes to the aperture AP2 relative to the lower portion 61 is referred to as a protrusion 622. A portion which protrudes to the aperture AP3 relative to the lower portion 61 is referred to as a protrusion 623.

The organic layer OR1 is in contact with the lower electrode LE1 through the aperture AP1, covers the lower electrode LE1 and overlaps part of the rib 5. The upper electrode UE1 faces the lower electrode LE1 and is provided on the organic layer OR1. Further, the upper electrode UE1 is in contact with a side surface of the lower portion 61. The organic layer OR1 and the upper electrode UE1 are located on the lower side relative to the upper portion 62.

The organic layer OR2 is in contact with the lower electrode LE2 through the aperture AP2, covers the lower electrode LE2 and overlaps part of the rib 5. The upper electrode UE2 faces the lower electrode LE2 and is provided on the organic layer OR2. Further, the upper electrode UE2 is in contact with a side surface of the lower portion 61. The organic layer OR2 and the upper electrode UE2 are located on the lower side relative to the upper portion 62.

The organic layer OR3 is in contact with the lower electrode LE3 through the aperture AP3, covers the lower electrode LE3 and overlaps part of the rib 5. The upper electrode UE3 faces the lower electrode LE3 and is provided on the organic layer OR3. Further, the upper electrode UE3 is in contact with a side surface of the lower portion 61. The organic layer OR3 and the upper electrode UE3 are located on the lower side relative to the upper portion 62.

In the example shown in FIG. 3, subpixels SP1, SP2 and SP3 include cap layers (optical adjustment layers) CP1, CP2 and CP3 for adjusting the optical property of the light emitted from the light emitting layers of the organic layers OR1, OR2 and OR3.

The cap layer CP1 is located in the aperture AP1, is located on the lower side relative to the upper portion 62 and is provided on the upper electrode UE1. The cap layer CP2 is located in the aperture AP2, is located on the lower side relative to the upper portion 62 and is provided on the upper electrode UE2. The cap layer CP3 is located in the aperture AP3, is located on the lower side relative to the upper portion 62 and is provided on the upper electrode UE3.

Sealing layers SE1, SE2 and SE3 are provided in subpixels SP1, SP2 and SP3, respectively.

The sealing layer SE1 is in contact with the cap layer CP1 and the lower and upper portions 61 and 62 of the partition 6 and continuously covers the members of subpixel SP1. The sealing layer SE1 does not comprise a void under the protrusion 621 of the partition 6.

The sealing layer SE2 is in contact with the cap layer CP2 and the lower and upper portions 61 and 62 of the partition 6 and continuously covers the members of subpixel SP2. The sealing layer SE2 does not comprise a void under the protrusion 622 of the partition 6.

The sealing layer SE3 is in contact with the cap layer CP3 and the lower and upper portions 61 and 62 of the partition 6 and continuously covers the members of subpixel SP3. The sealing layer SE3 does not comprise a void under the protrusion 623 of the partition 6.

The sealing layers SE1, SE2 and SE3 are covered with a protective layer 13.

In the example shown in FIG. 3, part of the organic layer OR1, part of the upper electrode UE1 and part of the cap layer CP1 are located between the partition 6 and the sealing layer SE1, are provided on the upper portion 62 and are spaced apart from the portions located on the lower side relative to the upper portion 62.

Part of the organic layer OR2, part of the upper electrode UE2 and part of the cap layer CP2 are located between the partition 6 and the sealing layer SE2, are provided on the upper portion 62 and are spaced apart from the portions located on the lower side relative to the upper portion 62.

Part of the organic layer OR3, part of the upper electrode UE3 and part of the cap layer CP3 are located between the partition 6 and the sealing layer SE3, are provided on the upper portion 62 and are spaced apart from the portions located on the lower side relative to the upper portion 62.

The insulating layer 12 is an organic insulating layer. The rib 5 and the sealing layers SE1, SE2 and SE3 are inorganic insulating layers.

The sealing layers SE1, SE2 and SE3 are formed of, for example, the same inorganic insulating material.

The rib 5 is formed of silicon nitride (SiNx) as an example of inorganic insulating materials. It should be noted that the rib 5 may be formed as, as another inorganic insulating material, a single-layer body of one of silicon oxide (SiOx), silicon oxynitride (SiON) and aluminum oxide (Al₂O₃). The rib 5 may be formed as a stacked layer body of a combination consisting of at least two of a silicon nitride layer, a silicon oxide layer, a silicon oxynitride layer and an aluminum oxide layer.

The sealing layers SE1, SE2 and SE3 are formed of silicon nitride (SiNx) as an example of inorganic insulating materials. It should be noted that the sealing layers SE1, SE2 and SE3 may be formed as, as another inorganic insulating material, a single-layer body of one of silicon oxide (SiOx), silicon oxynitride (SiON) and aluminum oxide (Al₂O₃). Each of the sealing layers SE1, SE2 and SE3 may be formed as a stacked layer body of a combination consisting of at least two of a silicon nitride layer, a silicon oxide layer, a silicon oxynitride layer and an aluminum oxide layer. Thus, the sealing layers SE1, SE2 and SE3 may be formed of the same material as the rib 5.

The lower portion 61 of the partition 6 is formed of a conductive material and is electrically connected to the upper electrodes UE1, UE2 and UE3. Both the lower portion 61 and the upper portion 62 of the partition 6 may be conductive.

The thickness of the rib 5 is sufficiently less than the thicknesses of the partition 6 and the insulating layer 12. For example, the thickness of the rib 5 is greater than or equal to 200 nm but less than or equal to 400 nm.

The thickness of the lower portion 61 of the partition 6 (the thickness from the upper surface of the rib 5 to the lower surface of the upper portion 62) is greater than that of the rib 5.

The thickness of the sealing layer SE1, the thickness of the sealing layer SE2 and the thickness of the sealing layer SE3 are substantially equal to each other and are, for example, approximately 1 μm.

Each of the lower electrodes LE1, LE2 and LE3 may be formed of a transparent conductive material such as ITO or may comprise a multilayer structure of a metal material such as silver (Ag) and a transparent conductive material. Each of the upper electrodes UE1, UE2 and UE3 is formed of, for example, a metal material such as an alloy of magnesium and silver (MgAg). Each of the upper electrodes UE1, UE2 and UE3 may be formed of a transparent conductive material such as ITO.

Each of the organic layers OR1, OR2 and OR3 includes a plurality of functional layers such as a hole injection layer, a hole transport layer, an electron blocking layer, a hole blocking layer, an electron transport layer and an electron injection layer. The organic layer OR1 includes a light emitting layer EM1. The organic layer OR2 includes a light emitting layer EM2. The light emitting layer EM2 is formed of a material different from that of the light emitting layer EM1. The organic layer OR3 includes a light emitting layer EM3. The light emitting layer EM3 is formed of a material different from the materials of the light emitting layers EM1 and EM2.

The material of the light emitting layer EM1, the material of the light emitting layer EM2 and the material of the light emitting layer EM3 are materials which emit light in different wavelength ranges.

For example, the light emitting layer EM1 is formed of a material which emits light in a blue wavelength range. The light emitting layer EM2 is formed of a material which emits light in a green wavelength range. The light emitting layer EM3 is formed of a material which emits light in a red wavelength range.

The cap layers CP1, CP2 and CP3 are formed by, for example, a multilayer body of transparent thin films. As the thin films, the multilayer body may include a thin film formed of an inorganic material and a thin film formed of an organic material. These thin films have refractive indices different from each other. The materials of the thin films constituting the multilayer body are different from the materials of the upper electrodes UE1, UE2 and UE3 and are also different from the materials of the sealing layers SE1, SE2 and SE3. It should be noted that the cap layers CP1, CP2 and CP3 may be omitted.

The protective layer 13 is formed of a multilayer body of transparent thin films. For example, as the thin films, the multilayer body includes a thin film formed of an inorganic material and a thin film formed of an organic material.

Common voltage is applied to the partition 6. This common voltage is applied to each of the upper electrodes UE1, UE2 and UE3 which are in contact with the side surfaces of the lower portions 61. Pixel voltage is applied to the lower electrodes LE1, LE2 and LE3 through the pixel circuits 1 provided in subpixels SP1, SP2 and SP3, respectively.

When a potential difference is formed between the lower electrode LE1 and the upper electrode UE1, the light emitting layer EM1 of the organic layer OR1 emits light in a blue wavelength range. When a potential difference is formed between the lower electrode LE2 and the upper electrode UE2, the light emitting layer EM2 of the organic layer OR2 emits light in a green wavelength range. When a potential difference is formed between the lower electrode LE3 and the upper electrode UE3, the light emitting layer EM3 of the organic layer OR3 emits light in a red wavelength range.

Now, this specification explains an example of the manufacturing method of the display device DSP.

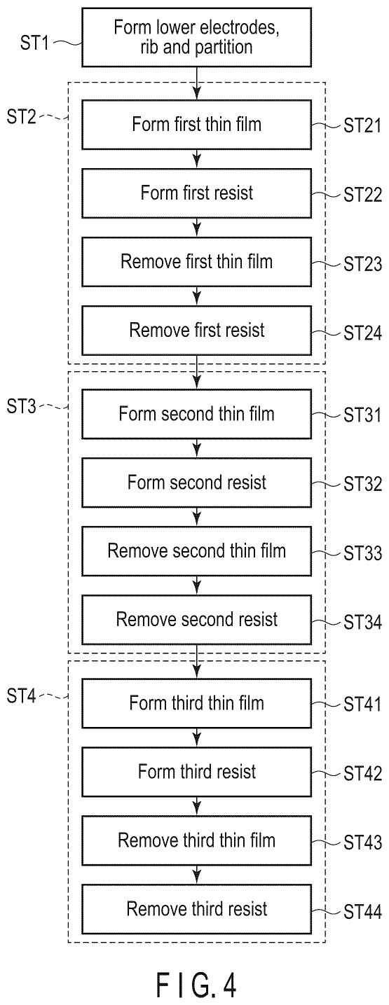

FIG. 4 is a flow diagram for explaining an example of the manufacturing method of the display device DSP.

The manufacturing method shown here roughly includes the process of preparing a processing substrate SUB comprising subpixels SP1, SP2 and SP3 (step ST1), the process of forming the display element 201 of subpixel SP1 (step ST2), the process of forming the display element 202 of subpixel SP2 (step ST3) and the process of forming the display element 203 of subpixel SP3 (step ST4).

In step ST1, first, the processing substrate SUB is prepared by forming the lower electrode LE1 of subpixel SP1, the lower electrode LE2 of subpixel SP2, the lower electrode LE3 of subpixel SP3, the rib 5 and the partition 6 above the substrate 10. As shown in FIG. 3, the circuit layer 11 and the insulating layer 12 are also formed between the substrate 10 and the lower electrodes LE1, LE2 and LE3.

In step ST2, first, a first thin film 31 including the light emitting layer EM1 is formed over subpixel SP1, subpixel SP2 and subpixel SP3 (step ST21). The first thin film 31 is a stacked layer body of the organic layer OR1, upper electrode UE1, cap layer CP1 and sealing layer SE1 shown in FIG. 3. Subsequently, a first resist 41 patterned into a predetermined shape is formed on the first thin film 31 (step ST22). Subsequently, part of the first thin film 31 is removed by etching using the first resist 41 as a mask (step ST23). At this time, for example, the first thin film 31 provided in subpixel SP2 and subpixel SP3 is removed. Subsequently, the first resist 41 is removed (step ST24). In this way, subpixel SP1 is formed. Subpixel SP1 comprises the display element 201 comprising the first thin film 31 having a predetermined shape.

In step ST3, first, a second thin film 32 including the light emitting layer EM2 is formed over subpixel SP1, subpixel SP2 and subpixel SP3 (step ST31). The second thin film 32 is a stacked layer body of the organic layer OR2, upper electrode UE2, cap layer CP2 and sealing layer SE2 shown in FIG. 3. Subsequently, a second resist 42 patterned into a predetermined shape is formed on the second thin film 32 (step ST32). Subsequently, part of the second thin film 32 is removed by etching using the second resist 42 as a mask (step ST33). At this time, for example, the second thin film 32 provided in subpixel SP1 and subpixel SP3 is removed. Subsequently, the second resist 42 is removed (step ST34). In this way, subpixel SP2 is formed. Subpixel SP2 comprises the display element 202 comprising the second thin film 32 having a predetermined shape.

In step ST4, first, a third thin film 33 including the light emitting layer EM3 is formed over subpixel SP1, subpixel SP2 and subpixel SP3 (step ST41). The third thin film 33 is a stacked layer body of the organic layer OR3, upper electrode UE3, cap layer CP3 and sealing layer SE3 shown in FIG. 3. Subsequently, a third resist 43 patterned into a predetermined shape is formed on the third thin film 33 (step ST42). Subsequently, part of the third thin film 33 is removed by etching using the third resist 43 as a mask (step ST43). At this time, for example, the third thin film 33 provided in subpixel SP1 and subpixel SP2 is removed. Subsequently, the third resist 43 is removed (step ST44). In this way, subpixel SP3 is formed. Subpixel SP3 comprises the display element 203 comprising the third thin film 33 having a predetermined shape.

It should be noted that the detailed illustrations of the second thin film 32, the second resist 42, the third thin film 33 and the third resist 43 are omitted.

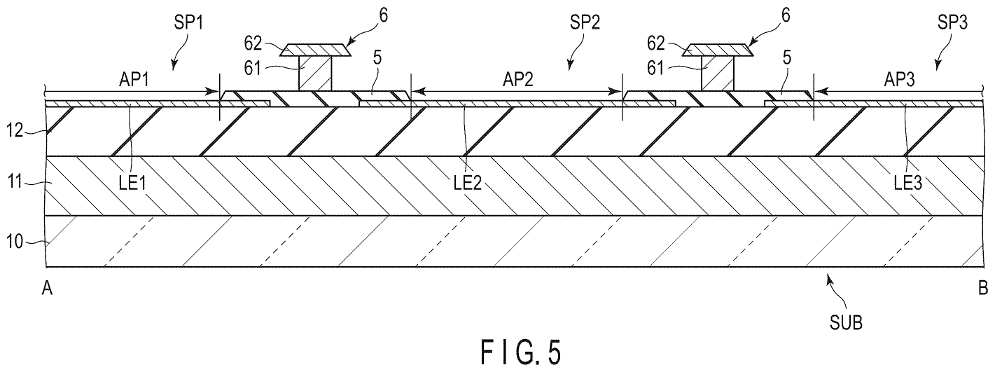

Now, this specification explains step ST1 and step ST2 with reference to FIG. 5 to FIG. 9. The section shown in each of FIG. FIG. 5 to FIG. 9 corresponds to, for example, the section taken along the A-B line of FIG. 2.

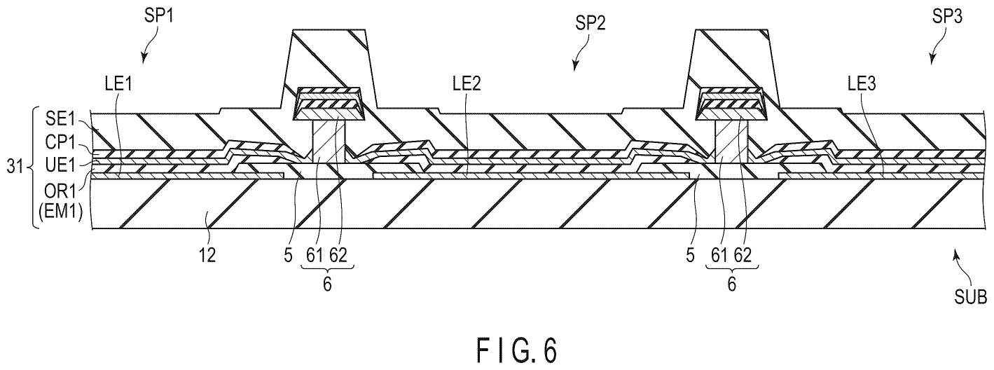

First, in step ST1, as shown in FIG. 5, the processing substrate SUB is prepared. The process of preparing the processing substrate SUB includes the process of forming the circuit layer 11 on the substrate 10, the process of forming the insulating layer 12 on the circuit layer 11, the process of forming the lower electrode LE1 of subpixel SP1, the lower electrode LE2 of subpixel SP2 and the lower electrode LE3 of subpixel SP3 on the insulating layer 12, the process of forming the rib 5 comprising the apertures AP1, AP2 and AP3 overlapping the lower electrodes LE1, LE2 and LE3, respectively, and the process of forming the partition 6 including the lower portion 61 provided on the rib 5 and the upper portion 62 provided on the lower portion 61 and protruding from the side surfaces of the lower portion 61. The rib 5 is formed of, for example, silicon nitride. Of the partition 6, at least the lower portion 61 is formed of a conductive material. In each of FIG. 6 to FIG. 9, the illustrations of the substrate 10 and the circuit layer 11 lower than the insulating layer 12 are omitted.

Subsequently, in step ST21, as shown FIG. 6, the first thin film 31 is formed over subpixel SP1, subpixel SP2 and subpixel SP3. The process of forming the first thin film 31 includes, on the processing substrate SUB, the process of forming the organic layer OR1 including the light emitting layer EM1, the process of forming the upper electrode UE1 on the organic layer OR1, the process of forming the cap layer CP1 on the upper electrode UE1 and the process of forming the sealing layer SE1 on the cap layer CP1. Thus, in the example shown in the figure, the first thin film 31 includes the organic layer OR1, the upper electrode UE1, the cap layer CP1 and the sealing layer SE1.

The organic layer OR1 is formed on each of the lower electrode LE1, the lower electrode LE2 and the lower electrode LE3 and is also formed on the partition 6. Of the organic layer OR1, the portion formed on each upper portion 62 is spaced apart from the portion formed on each of the lower electrodes. The various functional layers and the light emitting layer EM1 of the organic layer OR1 are formed by a vapor deposition method.

The upper electrode UE1 is formed on the organic layer OR1 immediately above each of the lower electrodes LE1, LE2 and LE3, covers the rib 5 and is in contact with the lower portions 61 of the partition 6. The upper electrode UE1 is also formed on the organic layer OR1 immediately above each upper portion 62. Of the upper electrode UE1, the portion which is formed immediately above each upper portion 62 is spaced apart from the portion which is formed immediately above each of the lower electrodes. The upper electrode UE1 is formed of, for example, an alloy of magnesium and silver by a vapor deposition method.

The cap layer CP1 is formed on the upper electrode UE1 immediately above each of the lower electrode LE1, the lower electrode LE2 and the lower electrode LE3, and is also formed on the upper electrode UE1 immediately above each upper portion 62. Of the cap layer CP1, the portion which is formed immediately above each upper portion 62 is spaced apart from the portion which is formed immediately above each of the lower electrodes. The transparent layer included in the cap layer CP1 is formed by a vapor deposition method. The inorganic layer included in the cap layer CP1 is formed of, for example, lithium fluoride by a vapor deposition method.

The sealing layer SE1 is formed so as to cover the cap layer CP1 and the partition 6. In other words, the sealing layer SE1 is formed on the cap layer CP1 immediately above each of the lower electrode LE1, the lower electrode LE2 and the lower electrode LE3, and is also formed on the cap layer CP1 immediately above each upper portion 62. In the sealing layer SE1, the portion which is formed immediately above each upper portion 62 is continuous with the portion which is formed immediately above each of the lower electrodes. The sealing layer SE1 is formed of, for example, silicon nitride by a chemical vapor deposition (CVD) method. The upper electrode UE1 is interposed between the rib 5 and the sealing layer SE1. The sealing layer SE1 is spaced apart from the rib 5.

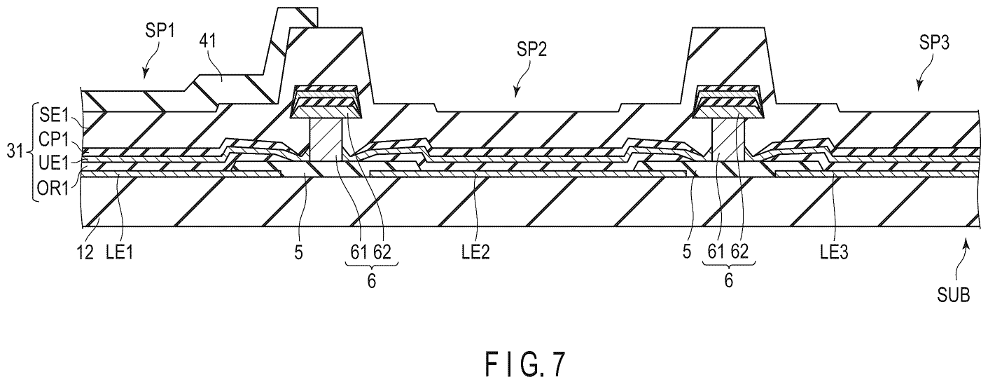

Subsequently, in step ST22, as shown in FIG. 7, the patterned first resist 41 is formed on the sealing layer SE1. The first resist 41 covers the first thin film 31 of subpixel SP1, and the first thin film 31 is exposed from the first resist 41 in subpixels SP2 and SP3. Thus, the first resist 41 overlaps the sealing layer SE1 located immediately above the lower electrode LE1. The first resist 41 extends from subpixel SP1 to the upper side of the partition 6. On the partition 6 between subpixel SP1 and subpixel SP2, the first resist 41 is provided on the subpixel SP1 side (the left side of the figure), and the sealing layer SE1 is exposed from the first resist 41 on the subpixel SP2 side (the right side of the figure). The sealing layer SE1 is exposed from the first resist 41 in subpixel SP2 and subpixel SP3.

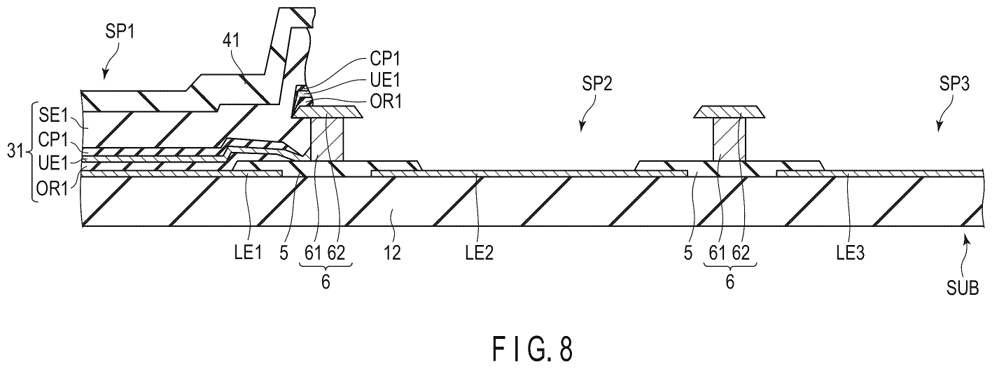

Subsequently, in step ST23, as shown in FIG. 8, etching is applied using the first resist 41 as a mask. By this process, the first thin film 31 exposed from the first resist 41 in subpixels SP2 and SP3 is removed, and the first thin film 31 remains in subpixel SP1.

The process of removing the first thin film 31 is, for example, as follows.

First, dry etching is performed using the first resist 41 as a mask to remove the sealing layer SE1 exposed from the first resist 41.

Subsequently, wet etching is performed using the first resist 41 as a mask to remove the inorganic layer of the cap layer CP1 exposed from the sealing layer SE1.

Subsequently, dry etching is performed using the first resist 41 as a mask to remove the transparent layer of the cap layer CP1 exposed from the inorganic layer.

Subsequently, wet etching is performed using the first resist 41 as a mask to remove the upper electrode UE1 exposed from the transparent layer.

Subsequently, dry etching is performed using the first resist 41 as a mask to remove the organic layer OR1 exposed from the upper electrode UE1.

In this way, the lower electrode LE2 is exposed in subpixel SP2, and the rib 5 surrounding the lower electrode LE2 is exposed. In subpixel SP3, the lower electrode LE3 is exposed, and the rib 5 surrounding the lower electrode LE3 is exposed. On the partition 6 between subpixel SP1 and subpixel SP2, the subpixel SP2 side is exposed. Further, the partition 6 between subpixel SP2 and subpixel SP3 is exposed.

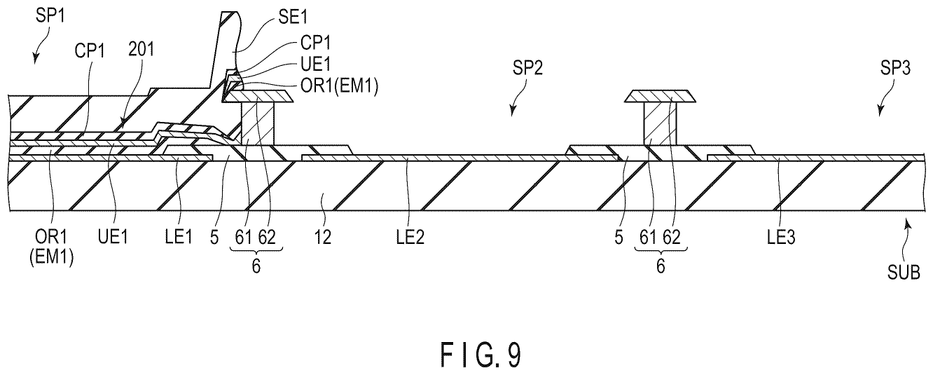

Subsequently, in step ST24, as shown in FIG. 9, the first resist 41 is removed. Thus, the sealing layer SE1 of subpixel SP1 is exposed. Through these steps ST21 to ST24, the display element 201 is formed in subpixel SP1. The display element 201 consists of the lower electrode LE1, the organic layer OR1 including the light emitting layer EM1, the upper electrode UE1 and the cap layer CP1. The display element 201 is covered with the sealing layer SE1.

A stacked layer body of the organic layer OR1 including the light emitting layer EM1, the upper electrode UE1, the cap layer CP1 and the sealing layer SE1 is formed on the partition 6 between subpixel SP1 and subpixel SP2. Of the partition 6, the portion on the subpixel SP1 side is covered with the sealing layer SE1. It should be noted that the stacked layer body on the partition 6 shown in FIG. 9 is completely eliminated in some cases.

Steps ST31 to ST34 shown in FIG. 4 are similar to steps ST21 to ST24 described above. Through these steps ST31 to ST34, the display element 202 is formed in subpixel SP2 shown in FIG. 3. The display element 202 consists of the lower electrode LE2, the organic layer OR2 including the light emitting layer EM2, the upper electrode UE2 and the cap layer CP2. The display element 202 is covered with the sealing layer SE2.

Steps ST41 to ST44 shown in FIG. 4 are also similar to steps ST21 to ST24 described above. Through these steps ST41 to ST44, the display element 203 is formed in subpixel SP3 shown in FIG. 3. The display element 203 consists of the lower electrode LE3, the organic layer OR3 including the light emitting layer EM3, the upper electrode UE3 and the cap layer CP3. The display element 203 is covered with the sealing layer SE3.

Now, this specification explains a CVD device for forming the sealing layers SE1, SE2 and SE3.

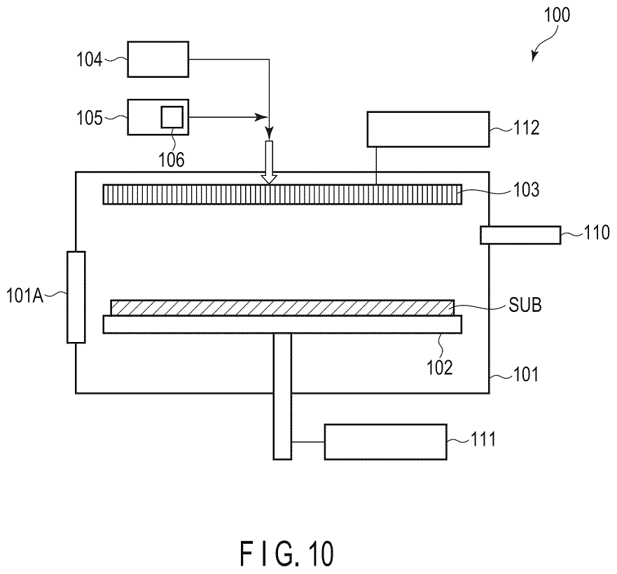

FIG. 10 is a diagram for explaining a configuration example of a CVD device 100.

The CVD device 100 comprises a chamber 101, a stage 102, a shower head 103, a material gas supply mechanism 104 and a cleaning gas supply mechanism 105.

The chamber 101 comprises a gate 101A for carrying the processing substrate SUB into the chamber 101 and carrying the processing substrate SUB out of the chamber 101. The stage 102 and the shower head 103 are provided inside the chamber 101. An evacuation device 110 is connected to the chamber 101. The processing substrate SUB explained here is prepared by, for example, when the first thin film 31 is formed, forming the circuit layer 11, the insulating layer 12, the lower electrodes LE1, LE2 and LE3, the rib 5, the partition 6, the organic layer OR1, the upper electrode UE1 and the cap layer CP1 above the substrate 10.

The stage 102 supports the processing substrate SUB which is carried in. A high-frequency power source 111 is connected to the stage 102. The stage 102 may be grounded, or high-frequency electricity may be supplied from the high-frequency power source 111 to the stage 102. The frequency of the high-frequency power source 111 is, for example, 13.56 MHz.

The shower head 103 is provided so as to face the stage 102. A high-frequency power source 112 is connected to the shower head 103. The shower head 103 may be grounded, or high-frequency electricity may be supplied from the high-frequency power source 112 to the shower head 103. The frequency of the high-frequency power source 112 is, for example, 13.56 MHz.

The material gas supply mechanism 104 supplies a material gas for forming a sealing layer by silicon nitride (SiN) to the shower head 103. To the gas supplied from the material gas supply mechanism 104, for example, a mixture of silicon hydride (SiH₄), nitrous oxide (N₂O) and nitrogen (N₂) is applied.

The cleaning gas supply mechanism 105 supplies a cleaning gas for cleaning the inside of the chamber 101 to the shower head 103. The gas supplied from the cleaning gas supply mechanism 105 is introduced into the chamber 101 through the shower head 103 which is on the same route as the gas supplied from the material gas supply mechanism 104. To the gas supplied from the cleaning gas supply mechanism 105, for example, a mixture of nitrogen trifluoride (NF₃) and argon (Ar) is applied.

The cleaning gas supply mechanism 105 comprises a remote plasma source 106. The remote plasma source 106 generates plasma by exciting the cleaning gas. The radical in the plasma generated in the remote plasma source 106 is introduced into the chamber 101 through the shower head 103.

The CVD device 100 comprises a deposition mode, an etching mode and a cleaning mode.

In the deposition mode, after the processing substrate SUB is carried into the chamber 101, the CVD device 100 firstly introduces a gas containing a material gas into the chamber 101 via the shower head 103 from the material gas supply mechanism 104. The stage 102 is grounded, and further, high-frequency electricity is supplied to the shower head 103 from the high-frequency power source 111. By this configuration, silicon nitride is deposited on the processing substrate SUB. In the deposition mode, a cleaning gas is not introduced into the chamber 101.

In the etching mode, the CVD device 100 firstly stops the introduction of the material gas and introduces a gas containing a cleaning gas into the chamber 101 via the shower head 103 from the cleaning gas supply mechanism 105. By supplying high-frequency electricity to the stage 102 from the high-frequency power source 112 and applying bias between the stage 102 and the shower head 103, of the introduced gas, argon gas induces discharge, and a radical formed of nitrogen trifluoride is generated. Anisotropic dry etching for removing part of the silicon nitride deposited on the processing substrate SUB is performed.

In the cleaning mode, after the processing substrate SUB is carried out of the chamber 101, the CVD device 100 firstly introduces a gas containing a cleaning gas into the chamber 101 via the shower head 103 from the cleaning gas supply mechanism 105. At this time, bias is not applied between the stage 102 and the shower head 103. The radical of nitrogen trifluoride generated in the remote plasma source 106 is introduced into the chamber 101 via the shower head 103. By this process, the inside of the chamber 101 is cleaned by isotropic dry etching.

Now, this specification explains the formation method of a sealing layer by the CVD device 100 described above.

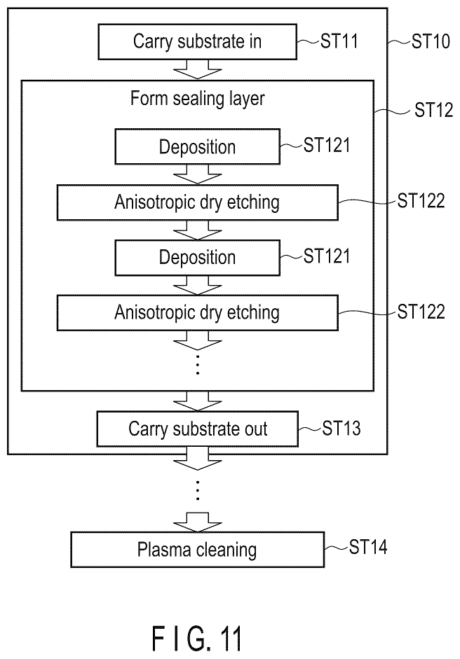

FIG. 11 is a diagram for explaining the formation method of a sealing layer.

A process for forming a sealing layer on a single processing substrate SUB (step ST10) includes a substrate carry-in process (step ST11), a sealing layer formation process (step ST12) and a substrate carry-out process (step ST13). Each process is explained below.

First, a processing substrate SUB in which a cap layer is formed is carried into the chamber 101 (step ST11). The processing substrate SUB carried from the gate 101A is provided on the stage 102.

Subsequently, a sealing layer is formed on the processing substrate SUB (step ST12). The process of forming a sealing layer includes a deposition process (step ST121) and an etching process (step ST122).

In the deposition process (step ST121), first, a gas containing a material gas is introduced into the chamber 101 from the material gas supply mechanism 104 to control the pressure of the inside of the chamber 101. At this time, the gas from the cleaning gas supply mechanism 105 is not introduced. Subsequently, high-frequency electricity is supplied to the shower head 103 in a state where the stage 102 is grounded. By this configuration, silicon nitride is deposited on the processing substrate SUB. For example, in a single deposition process, silicon nitride is deposited so as to have a thickness greater than or equal to 0.5 μm. Subsequently, the introduction of the gas from the material gas supply mechanism 104 is stopped, and the supply of high-frequency electricity is stopped. Subsequently, the evacuation device 110 is operated to evacuate the residual gas of the inside of the chamber 101.

In the etching process (step ST122), firstly, a gas containing a cleaning gas is introduced into the chamber 101 from the cleaning gas supply mechanism 105 to control the pressure of the inside of the chamber 101. The gas containing the cleaning gas is supplied to the shower head 103 which is on the same route as the gas containing the material gas. At this time, the gas from the material gas supply mechanism 104 is not introduced. Subsequently, high-frequency electricity is supplied to the stage 102. It should be noted that the radical of nitrogen trifluoride generated in the remote plasma source 106 may be introduced into the chamber 101 via the shower head 103. In this way, anisotropic dry etching for removing part of the silicon nitride deposited on the processing substrate SUB is performed. For example, in a single etching process, silicon nitride having a thickness greater than or equal to 0.2 μm is removed. Subsequently, the introduction of the gas from the cleaning gas supply mechanism 105 is stopped, and the supply of high-frequency electricity is stopped. Subsequently, the evacuation device 110 is operated to evacuate the residual gas of the inside of the chamber 101. This etching process (step ST122) is performed at a temperature (ordinary temperature) lower than that of the deposition process (step ST121).

In the sealing layer formation process (step ST12), a combination of the deposition process (step ST121) and the etching process (step ST122) is performed at least twice. For example, a combination of the deposition process (step ST121) and the etching process (step ST122) should be preferably performed three times or more to prevent the formation of a void in the sealing layer. To reduce the manufacturing cost and improve the manufacturing yield, the combination should be preferably performed seven times or less.

This process for forming a sealing layer on the processing substrate SUB (step ST10) is applied to a plurality of processing substrates SUB. Subsequently, plasma cleaning is applied to the inside of the chamber 101 (step ST14).

In the cleaning process (ST14), a gas containing a cleaning gas is introduced into the chamber 101 from the cleaning gas supply mechanism 105. The gas containing the cleaning gas is supplied to the shower head 103 which is on the same route as the gas containing the material gas. At this time, bias is not applied between the stage 102 and the shower head 103. The radical of nitrogen trifluoride generated in the remote plasma source 106 is introduced into the chamber 101 via the shower head 103. By this process, the inner sides of the shower head 103 and the chamber 101 are cleaned by isotropic dry etching.

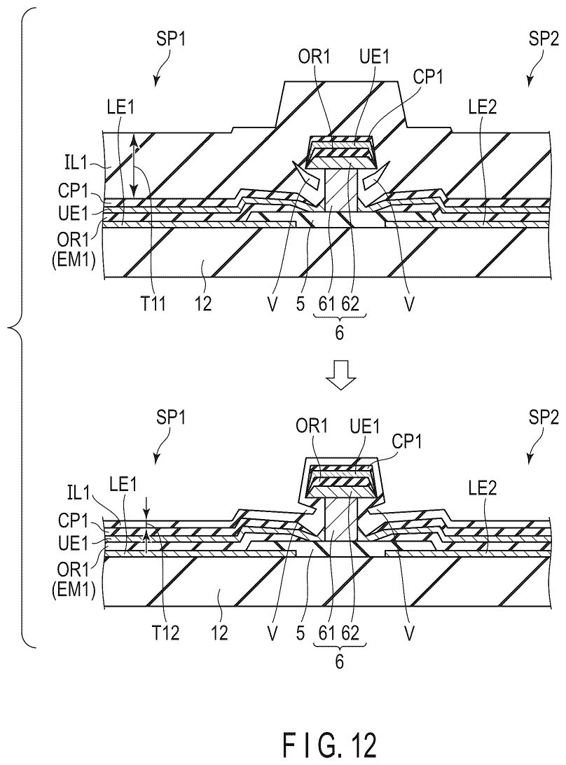

Here, this specification explains the sealing layer formation process (step ST12) with reference to FIG. 12 to FIG. 14. In FIG. 12 to FIG. 14, the section of the processing substrate including subpixel SP1 and subpixel SP2 is shown, and the illustrations of the substrate 10 and the circuit layer 11 lower than the insulating layer 12 are omitted.

First, in the deposition process (step ST121), as shown in the upper part of FIG. 12, an inorganic insulating layer IL1 is formed by depositing silicon nitride on the processing substrate in which the cap layer CP1 is formed. The silicon nitride is deposited on the cap layer CP1, reaches the lower side of the upper portion 62 of the partition 6 and is in contact with the partition 6.

When this specification focuses attention on the inorganic insulating layer IL1 located in subpixel SP1, the inorganic insulating layer IL1 is in contact with the cap layer CP1, is in contact with a side surface of the lower portion 61 of the partition 6 and is in contact with the bottom surface of the upper portion 62 of the partition 6. The inorganic insulating layer IL1 comprises a closed void V under the upper portion 62. The thickness T11 of the inorganic insulating layer IL1 formed in a single deposition process is, for example, 0.5 μm immediately above the lower electrode LE1.

Subsequently, in the etching process (step ST122), as shown in the lower part of FIG. 12, anisotropic dry etching is applied to the entire inorganic insulating layer IL1 without using a resist. In anisotropic dry etching, side etching does not easily make progress compared to isotropic dry etching. Therefore, the film thickness of the inorganic insulating layer IL1 located immediately above each of the lower electrodes LE1 and LE2 is reduced, and the film thickness of the inorganic insulating layer IL1 located immediately above the upper portion 62 of the partition 6 is reduced. Further, the inorganic insulating layer IL1 on the distal end side of each void V is removed, and each void V is opened. After the anisotropic dry etching, immediately above the lower electrode LE1, the thickness T12 of the inorganic insulating layer IL1 is, for example, 0.3 μm.

The inorganic insulating layer IL1 located under the upper portion 62 of the partition 6 is not substantially removed. In other words, after the anisotropic dry etching, the inorganic insulating layer IL1 covers the side surfaces of the lower portion 61 of the partition 6 and the bottom surface of the upper portion 62 of the partition 6.

Subsequently, a combination of the deposition process (step ST121) and the etching process (step ST122) is repeatedly performed.

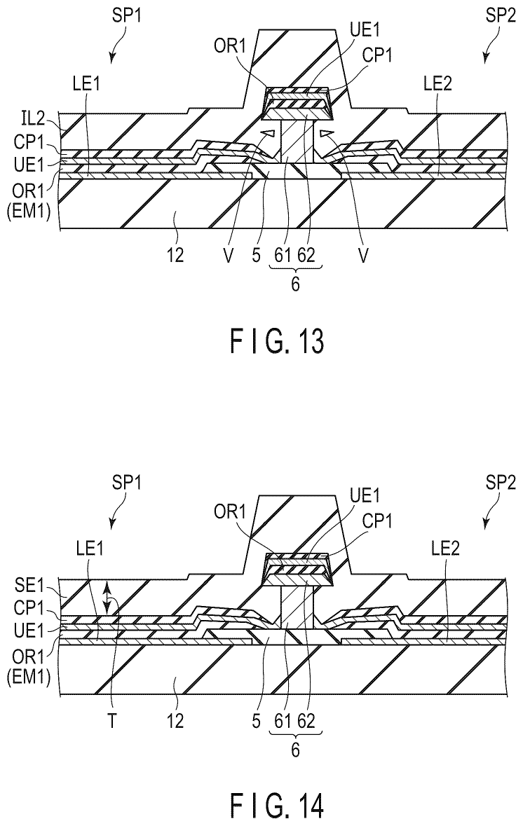

As shown in FIG. 13, for example, an inorganic insulating layer IL2 which is formed after a combination of the deposition process (step ST121) and the etching process (step ST122) is performed twice comprises a closed void V under the upper portion 62. When the cross-sectional view of the upper part of FIG. 12 is compared with the cross-sectional view of FIG. 13, the cross-sectional area of the void V immediately after the formation of the inorganic insulating layer IL2 is less than that of the void V immediately after the formation of the inorganic insulating layer IL′.

As shown in FIG. 14, for example, the sealing layer SE1 which is formed after a combination of the deposition process (step ST121) and the etching process (step ST122) is performed three times or more fills the lower side of the upper portion 62 without the formation of a void under the upper portion 62.

By forming a sealing layer which does not include a void in this manner, a crack based on a void is prevented, and the sealing performance of the sealing layer can be improved. In this way, the reduction in reliability can be prevented.

By repeating the deposition process and the etching process, the sealing performance can be sufficiently performed with a sealing layer having a thickness T of approximately 1 μm. As the thickness of the sealing layer which covers each display element is reduced, the reduction in the transmittance of the light emitted from the display elements is prevented. For example, silicon nitride which forms each sealing layer has the property of slightly absorbing a blue wavelength (a wavelength range less than or equal to 450 nm). Therefore, when a sealing layer is formed of silicon nitride, the thickness of the sealing layer should be preferably less in a range which can assure the sealing performance, and is, for example, less than or equal to 2 μm. By this configuration, the transmittance of a blue wavelength is improved.

In the process of removing part of the first thin film 31 described above, before the etching of the sealing layer SE1, in subpixels SP2 and SP3, the upper electrode UE1 covers the rib 5 between the partition 6 and the organic layer OR1. Thus, the sealing layer SE1 is not in contact with the rib 5. The upper electrode UE1 functions as an etching stopper layer. The etching rate of the upper electrode UE1 is less than that of the sealing layer SE1. Thus, regarding the dry etching of the sealing layer SE1, after the sealing layer SE1 is completely removed, the progress of dry etching can be stopped in the upper electrode UE1. By this configuration, the rib 5 is not substantially damaged when dry etching is applied to the sealing layer SE1. This configuration prevents the formation of an undesired hole (a penetration path for moisture) which penetrates the rib 5 so as to expose the insulating layer 12. Further, the configuration prevents the change in the colors of the lower electrodes because of the effect of undesired moisture. Moreover, the configuration prevents an occurrence of pixel defects in which the organic EL elements do not emit light because of damage to the anodes and the organic EL elements.

As explained above, the present embodiment can provide a manufacturing method of a display device and a CVD device such that the reduction in reliability can be prevented and the manufacturing yield can be improved.

All of the manufacturing methods of a display device and CVD devices that can be implemented by a person of ordinary skill in the art through arbitrary design changes to the manufacturing method and CVD device described above as the embodiments of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or by adding or omitting a step or changing the condition of a step, all of the modifications fall within the scope of the present invention as long as they are in keeping with the spirit of the invention.

Further, other effects which may be obtained from the above embodiments and are self-explanatory from the descriptions of the specification or can be arbitrarily conceived by a person of ordinary skill in the art are considered as the effects of the present invention as a matter of course.

What is claimed is:

1. A manufacturing method of a display device, comprising:
preparing a processing substrate by forming a lower electrode above a substrate, forming a rib comprising an aperture overlapping the lower electrode, and forming a partition including a lower portion located on the rib and an upper portion located on the lower portion and protruding from a side surface of the lower portion;
forming an organic layer on the lower electrode in the aperture;
forming an upper electrode which is located on the organic layer and is in contact with the partition;
forming a cap layer on the upper electrode; and
forming a sealing layer which is located on the cap layer and is in contact with the partition, wherein
the forming the sealing layer includes:
after the processing substrate in which the cap layer is formed is carried into a chamber,
a deposition process of introducing a material gas into the chamber, depositing silicon nitride on the processing substrate, stopping introduction of the material gas and evacuating a residual gas of inside of the chamber; and
following the deposition process, an etching process of introducing a cleaning gas into the chamber through a same route as the material gas, performing anisotropic dry etching for removing part of the silicon nitride deposited on the processing substrate, and evacuating a residual gas of the inside of the chamber, and
a combination of the deposition process and the etching process is performed at least twice.

2. The manufacturing method of claim 1, wherein
in the single deposition process, silicon nitride having a thickness greater than or equal to 0.5 μm is formed, and
in the single etching process, silicon nitride having a thickness greater than or equal to 0.2 μm is removed.

3. The manufacturing method of claim 1, wherein
after the processing substrate is carried out of the chamber, the cleaning gas is introduced into the chamber through a same route as the material gas, and the inside of the chamber is cleaned by isotropic dry etching.

4. The manufacturing method of claim 1, wherein
the etching process is performed at a temperature lower than the deposition process.

5. The manufacturing method of claim 1, further comprising:
forming a patterned resist on the sealing layer; and
performing dry etching for the sealing layer using the resist as a mask.

6. The manufacturing method of claim 5, wherein
the rib is formed of silicon nitride,
the upper electrode is interposed between the rib and the sealing layer, and
the sealing layer is spaced apart from the rib.

7. The manufacturing method of claim 6, wherein
the upper electrode is formed of an alloy of magnesium (Mg) and silver (Ag).

8. The manufacturing method of claim 7, wherein
the lower portion of the partition is formed of a conductive material.

9. A CVD device comprising:
a chamber;
a stage provided inside the chamber and supporting a processing substrate which is carried in;
a shower head facing the stage;
a material gas supply mechanism which supplies a material gas to the shower head; and
a cleaning gas supply mechanism which supplies a cleaning gas to the shower head,
wherein the CVD device is configured to:
introduce the material gas into the chamber via the shower head, ground the stage, supply high-frequency electricity to the shower head, deposit silicon nitride on the processing substrate, and stop introduction of the material gas; and
introduce the cleaning gas into the chamber via the shower head, supply high-frequency electricity to the stage, and perform anisotropic dry etching for removing part of the silicon nitride deposited on the processing substrate.

10. The CVD device of claim 9, further configured to, after the processing substrate is carried out of the chamber, introduce the cleaning gas into the chamber via the shower head and clean inside of the chamber by isotropic dry etching.
